(19) United States
(12) Patent Application Publication
(10) Pub. No.: US 2016/0219738 A1
(43) Pub. Date: Jul. 28, 2016

(54) METHOD FOR MANUFACTURING AN AIRTIGHT HOUSING INTENDED FOR ENCAPSULATING AN IMPLANTABLE DEVICE AND CORRESPONDING HOUSING

(71) Applicant: COMMISSARIAT A L'ENERGIE ATOMIQUE ET AUX ENERGIES ALTERNATIVES, Paris (FR)

(72) Inventors: Nicolas Karst, Folkling (FR); Simon Perraud, Bandol (FR)

(73) Assignee: COMMISSARIAT A L'ENERGIE ATOMIQUE ET AUX ENERGIES ALTERNATIVES, Paris (FR)

(21) Appl. No.: 14/917,213

(22) PCT Filed: Sep. 10, 2014
(86) PCT No.: PCT/IB2014/064391

§ 371 Date: Mar. 7, 2016

(30) Foreign Application Priority Data
Sep. 19, 2013 (FR) 1359004

(51) Int. Cl. H05K 5/06; B23K 26/20; H01M 2/10; B23K 1/18

(52) U.S. Cl. CPC H05K 5/069; B23K 1/18; B23K 26/206; H01M 2/1022; H01M 2220/30

(57) ABSTRACT

The invention relates to a method for manufacturing a thin airtight housing, which includes: (a) providing a first element in which a recess is made; (b) forming a solder joint in said recess, said joint being at least partially inserted in said recess; (c) placing a second element opposite said first element and said joint; (d) forming a first airtight seal between the first and second elements in order to assemble same and form an assembly; (e) placing a cover on top of said assembly; and (f) forming a second airtight seal between said assembly and said cover.

The invention relates to a method for making an airtight casing notably intended for encapsulating a device and more particularly an implantable medical device.

The invention also relates to such an airtight casing.

With longer life expectancy and increase in the number of persons affected with neurodegenerative diseases, the use of neurostimulators as a replacement or as an addition to drug treatments is increasingly adopted by practitioners.

Like other implantable biomedical devices such as heart stimulators, cardiac defibrillators, heart monitors, biomedical pumps or sensors, neurostimulation devices consist of a battery and of a set of electronic components encapsulated in a biocompatible metal casing (generally in titanium).

In addition to biocompatibility, the casing ensuring the encapsulation of the different components of the neurostimulator should be airtight in order to avoid any contact between the components and the biological tissues or fluids.

Neurostimulators presently used have a thickness comprised between 0.5 cm and 1 cm for a volume comprised between 15 cm³ and 30 cm³.

Such a volume considerably limits the implantation sites within the human body of these devices.

In order to address new implantation areas and to be as close as possible to the areas to be electrically stimulated, the volume occupied by the neurostimulators should be reduced.

To do this, different solutions of airtight and biocompatible encapsulation solutions were able to be proposed in the literature as an alternative to the conventionally used titanium casing.

Thus, the U.S. Pat. No. 5,750,926 of Schulman et al. describes a casing ensuring the encapsulation of the different components required for proper operation of a neurostimulator. It is obtained by attaching a metal lid to an insulating substrate. The shape of the metal lid was selected so that, once it is attached to the insulating substrate, the metal lid forms a cavity giving the possibility of receiving the set of components of the neurostimulator. Two steps are required for ensuring the seal of the casing: the first step provides the formation of a first airtight gasket between a metal frame and the insulating substrate, this gasket may be obtained by different methods such as for example diffusion welding or further brazing. The second step gives the possibility of producing a second airtight joint by localized welding (by laser welding for example) between the metal frame and the metal lid.

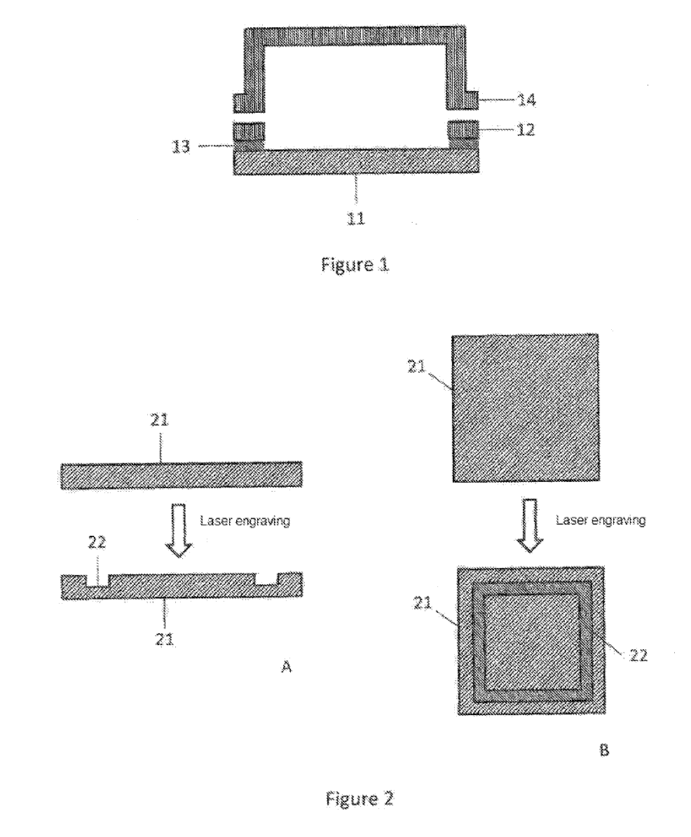

FIG. 1 describes a general case of the manufacturing a fine casing according to the state of the art.

Two main steps are required for obtaining this casing.

The first step consists in making a half-casing obtained by brazing a substrate 11 in an insulating material (ceramic for example) and a frame 12 in a metal material (in titanium for example), via the brazing joint 13. This brazing step has the purpose of hermetically sealing the substrate with the frame 12.

The second step gives the possibility of hermetically sealing the metal lid 14 with the frame 12 by laser welding localized at the junction between the metal lid 14 and the frame 12.

In practice, it proves to be difficult to reduce the thickness of the device after the encapsulation to below the limit of 1 mm.

The object of the invention is to further reduce the thickness of the encapsulation casings so as to implant them as close as possible to the areas to be electrically stimulated, without compromising their mechanical strength.

Indeed, an implantation as close as possible to the areas to be stimulated would notably avoid the use of long electrode-probes. Such probes are for example used for connecting an implanted casing in the chest of a patient to an area located in the head and they have risks of failure at the neck.

Thus, the invention relates to a method for making a fine hermetically sealed casing comprising the following steps:
(a) providing a first element in which a recess is made,
(b) forming a brazing joint in said recess, said joint being at least partly integrated into said recess,
(c) putting a second element facing said first element and said joint,
(d) forming a first hermetically sealed joint between the first and second elements in order to assemble them and form an assembly,
(e) superposing a lid to said assembly,
(f) forming a second hermetically sealed joint between said assembly and said lid.

The at least partial integration of the brazing joint into the thickness of the substrate gives the possibility of reducing the impact of the thickness of this joint on the total thickness of the casing.

The thickness of the casing is thus reduced, without modifying its mechanical strength.

In a first alternative embodiment of the method, the brazing joint is partly integrated into said recess, the second element then being planar.

In a second alternative embodiment, the brazing joint is totally integrated into said recess, the second element including a first protruding portion intended to penetrate into the recess during the step (c) for coming into contact with said brazing joint.

The first element may be a sheet-shaped substrate, the second element then being a metal frame. The first element may also be a metal frame, the second element then being a sheet-shaped substrate.

Preferably, the metal frame includes a second protruding portion, on its face opposite to the one intended to come into contact with the brazing joint.

In this case, the lid advantageously has a groove into which is inserted the second protruding portion, during step (e). This allows easy and accurate alignment between the lid and the metal frame.

This gives the possibility of suppressing any impact of this alternative embodiment on the thickness of the casing obtained by the method according to the invention.

Advantageously, during step (a), a cavity is also made in the substrate.

This gives the possibility of obtaining a casing having a larger cavity for encapsulation of components.

Advantageously, during step (b), the brazing joint is made as a thin layer covering the walls of the recess.

This gives the possibility of increasing the mechanical strength of the first hermetically sealed joint which will be obtained during step (d), the joint then covering the whole of the walls of the recess.

The invention also relates to a method for encapsulating a device consisting of applying the method for making a hermetically sealed casing according to the invention and of at least mounting one component of said device to be encapsulated on said first element, after step (b).

The invention also relates to a hermetically sealed casing comprising:
a first element including a recess,
a second element hermetically connected to the first element through a first joint, at least partly integrated into said recess and
a lid hermetically connected to the first or to the second element through a second joint.

In a first alternative embodiment, the second element is planar.

In a second alternative embodiment, the second element includes a first protruding portion introduced into said recess.

The first element may be a sheet-shaped substrate, the second element then being a metal frame. The first element may also be a metal frame, the second element then being a sheet-shaped substrate.

Preferably, the metal frame includes a second protruding portion in contact with the lid.

The lid then advantageously has a groove into which is inserted the second protruding portion.

Preferably, the substrate includes a cavity facing the lid.

The invention will be better understood and other objects, advantages and characteristics thereof will become more clearly apparent upon reading the description which follows and which is made with reference to the appended drawings, wherein:

FIG. 2 (2A-2B) illustrates a first step of the method according to the invention wherein the substrate of the encapsulation device is shaped so as to produce an engraving,

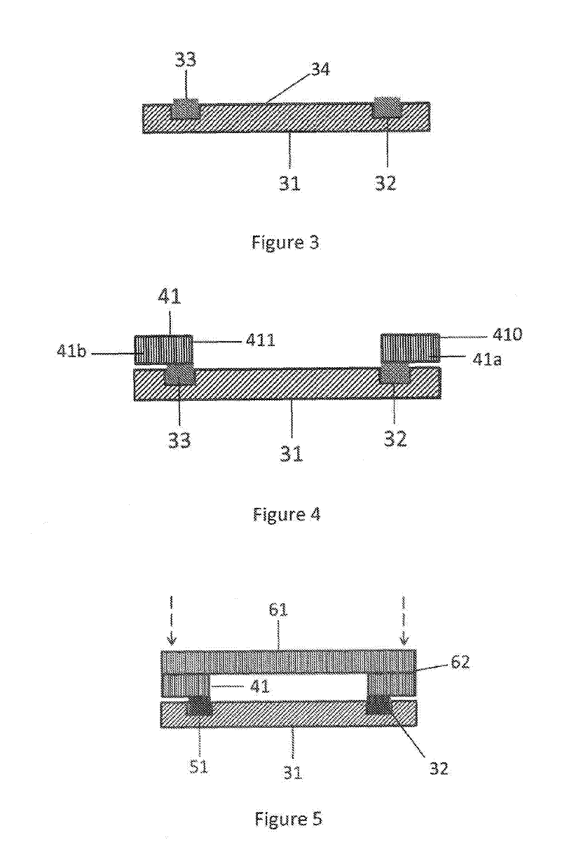

FIG. 3 is a sectional view illustrating a second step of the method according to the invention wherein the brazing joint is deposited in the engravement of the substrate,

FIG. 4 is a sectional view illustrating a third step of the method according to the invention wherein a metal frame is connected to the substrate by brazing,

FIG. 5 is a sectional view illustrating a fourth step of the method according to the invention wherein a metal lid is sealed on the metal frame,

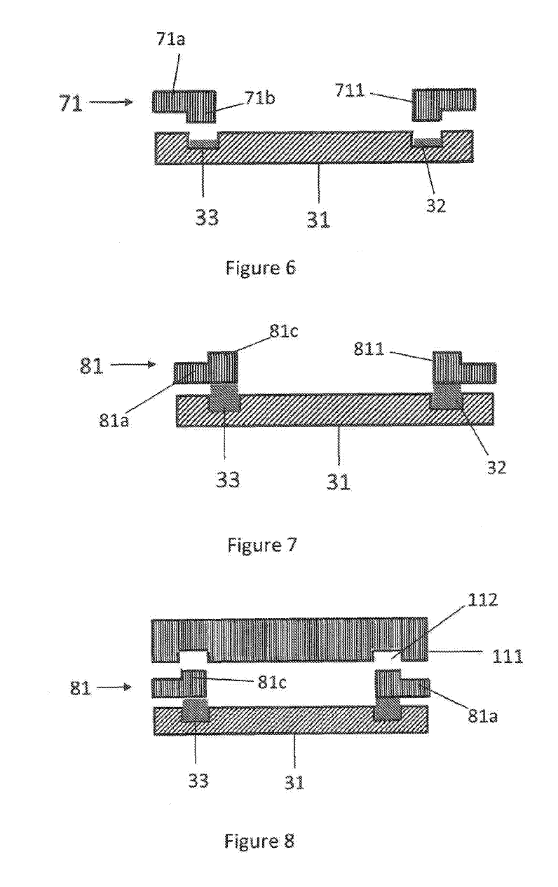

FIG. 6 is a sectional view illustrating an alternative embodiment of the second and third steps of the method according to the invention,

FIG. 7 is a sectional view illustrating another alternative embodiment of the second and third steps of the method according to the invention,

FIG. 8 is a sectional view illustrating an alternative embodiment of the fourth step of the method according to the invention,

FIG. 9 is a sectional view illustrating another alternative embodiment of the method combining the alternative embodiments illustrated in FIGS. 6 and 8,

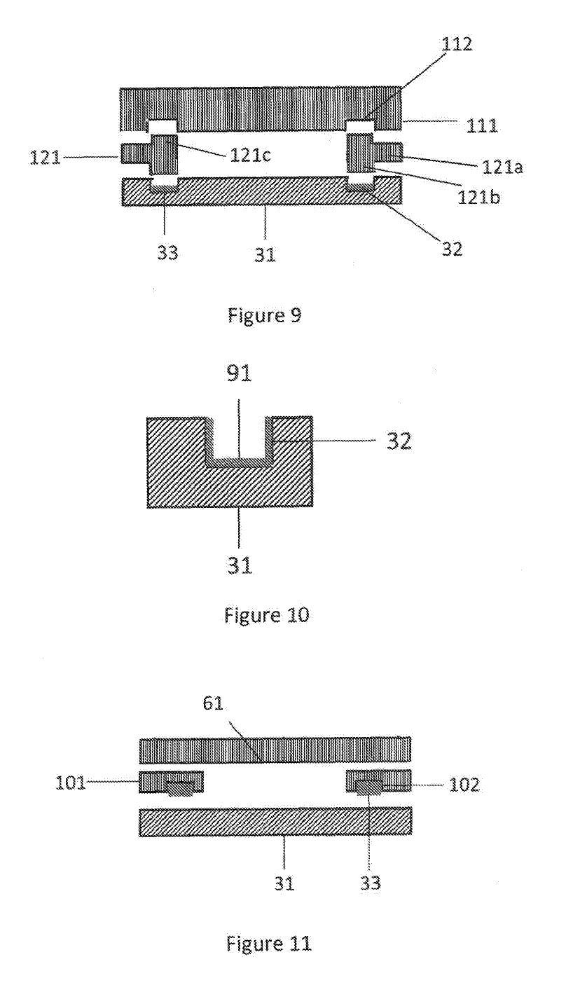

FIG. 10 is a partial sectional view illustrating an alternative embodiment of the second step of the method according to the invention,

FIG. 11 is a sectional view illustrating an alternative embodiment of the first, second and third steps of the method according to the invention,

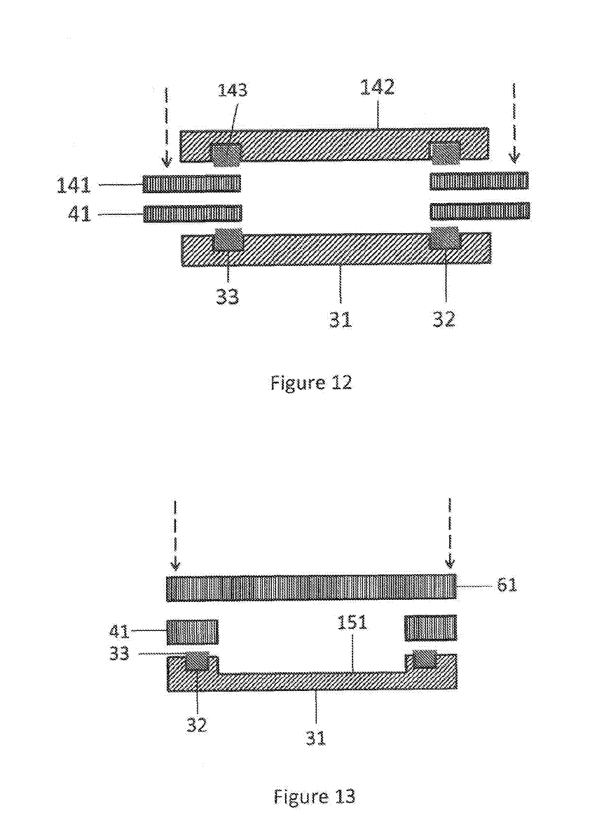

FIG. 12 is a sectional view illustrating an alternative embodiment of the fourth step of the method according to the invention, and

FIG. 13 is a sectional view illustrating an alternative embodiment of the first step of the method according to the invention.

FIGS. 2 to 5 illustrate the different steps for applying an exemplary method according to the invention giving the possibility of obtaining a casing encapsulating components and the thickness of which is reduced, by reducing the impact of the thickness of the brazing joint on the total thickness of the casing.

FIG. 2A is a sectional view of the substrate 21 before and after shaping (texturation) and FIG. 2B shows the substrate illustrated in FIG. 2A, but as seen from above.

The substrate 21 is advantageously a part in ceramic, preferably in alumina Al₂O₃ or Zirconia ZrO₂ stabilized with yttrium oxide Y₂O₃.

The substrate 21 may appear in the form of a plate or a sheet, with a square shape as illustrated in FIG. 2, with a circular shape, or with any other shapes in which this material may be made.

This plate or sheet may be made by strip casting methods from a casting suspension or slurry containing several constituents: some powder of the base material (Al₂O₃ for example), solvents, binders and diverse additives. Thus, after strip casting of the slurry, a plate or sheet of <<green ceramic>> is obtained.

The thickness of the substrate 21 before sintering (<<green ceramic>>) is comprised between 10 μm and 1 mm, advantageously between 20 μm and 150 μm, preferentially of the order of 100 μm.

In its <<green>> state, the substrate 21 is extremely easy to shape (texture). This property as well as the means required for achieving it, are well known one skilled in the art and mention may notably be made of the use of engraving or marking lasers. Mention may notably be made of the use of a laser of the Nd:YAG type allowing both engraving and marking of parts in ceramics and of metal parts.

Thus, as illustrated in FIG. 2, the substrate is engraved by means of a laser on a portion of its thickness in order to form a groove or a recess 22.

As illustrated by FIG. 2B, this groove also has a square shape.

Generally, this recess is conformed according to a closed curve. This curve is included in the periphery of the substrate and preferably homothetic with this periphery.

The depth of the groove 22 will depend on the thickness of the substrate 21. Indeed, in order not to embrittle too much the substrate 21, the depth of the groove 22 should be comprised between 5% and 80% of the total thickness of the substrate, preferentially 50%.

Thus, for a substrate 21 with a thickness of 100 μm, the depth of the groove 22 will be comprised between 5 μm and 80 μm, preferentially 50 μm.

The width of the groove 22 will depend on the width of the brazing joint 33 used for the brazing step.

Once the engraving 22 is achieved, sintering annealing is carried out in order to remove the organic components present in the <<green ceramic>> and to densify the material.

This sintering annealing may be carried out in different gaseous atmospheres, it is notably possible to carry out this sintering annealing in air.

The temperatures required for the sintering of the <<green ceramic>> will depend on the material and will be comprised between 1,200° C. and 1,700° C., preferentially 1,500° C. Ramps with a relatively slow rise in temperature comprised between 0.1° C./minute and 5° C./min, preferentially 1° C./min, will have to be used in order to allow total discharge of the organic components before attaining the temperature plateau at which sintering annealing will take place.

During the sintering annealing, a reduction of the dimensions of the substrate is observed along the three spatial axes by about 20%.

Thus, a substrate in <<green ceramic>> with a thickness of 100 μm, after sintering annealing will have a thickness of about 80 μm, also once the sintering annealing has been carried out, the thickness as well as the width of the groove will have decreased by about 20%.

It should be noted that shaping (texturation) of the ceramic may also be carried out after sintering of the green ceramic.

FIG. 3 illustrates a substrate 31 after shaping and sintering annealing and formation of a brazing joint 33 in the groove 32.

In FIG. 3, the brazing joint 33 is partly integrated into the substrate 31 since the joint fills the engraving and is found protruding relatively to the surface 34 of the substrate which is engraved. It may also be flush with the level of the surface of the substrate.

Other possible embodiments are described in the subsequent description.

The brazing joint 33 may be of a very diverse chemical nature depending on the targeted application.

Within the scope of an implantable biomedical application, one of the key points is the biocompatibility of the brazing joint 33. For example mention may be made of the use of a joint in a material based on titanium and nickel, known under the trade name TiNi50 or the use of a joint based on pure nickel. For example reference may be made to the document of Jiang “Development of ceramic to metal package for Bion microstimulator”—2005 which describes the nature and the physico-chemical properties of this type of brazing joint or of other types of joint which may potentially be used in the field of implantable biomedical devices.

The thickness of the brazing joint 33 will depend both on the depth of the groove 32 and on the thickness of the substrate 31.

If the example of a substrate 31 with a thickness of 80 μm and a groove 32 with a depth of 40 μm (corresponding to 50% of the thickness of the ceramic 31) is taken, it will be possible to use a brazing joint 33 with a thickness of 50 μm.

More generally, the thickness of the brazing joint 33 may be comprised between 0.1 μm and 500 μm.

The brazing joint 33 may appear as a massive frame in the sense that it may be positioned manually or automatically with an automated piece of equipment. A joint will be defined as massive as opposed to a joint as a thin layer. A brazing joint 33 as a thin layer (with a thickness comprised between 0.1 μm and 5 μm), obtained from different techniques for depositing thin layers, is described in the subsequent description.

It should be noted that the brazing joint 33 may be set into place before the sintering annealing of the ceramic substrate 21.

This brazing joint 33 may appear as a frame with a given thickness but may also appear as a slurry deposited in the groove 22 by deposition methods via a wet route such as screen printing or ink jet. By adding the brazing joint 33 before the sintering step, it will be possible to reinforce the mechanical strength of the groove 32 after the sintering annealing.

As illustrated in FIG. 4, a metal frame 41 is then put into contact with the brazing joint 33 partly positioned in the groove 32 of the substrate 31.

The frame 41 has a similar shape to that of the substrate, therefore here a square shape. FIG. 4 shows that the frame 41 is planar, it is made in metal.

The frame 41 comprises an external wall 410 and an internal wall 411, the outer wall being positioned at the perimeter of the substrate 31, while the inner wall is positioned inside this perimeter so as to come into contact with the joint 33.

The obtained assembly, illustrated in FIG. 4 is then brazed by means of a brazing oven in order to produce the brazing 51 between the substrate 31 and the metal frame 41 by means of the brazing joint 33.

Reference may be made to the document of Jiang “Development of ceramic to metal package for Bion microstimulator”—2005 which describes how to produce a brazing joint between an insulating substrate of the ceramic type and a metal part.

If one takes the example of the brazing joint 33 based on TiNi50, the brazing annealing may be carried out between 960° C. and 1,200° C., preferentially 1,035° C.

Advantageously, elements, in particular electronic components, to be encapsulated into the casing according to the invention will be positioned on the substrate after forming the brazing 51, producing a hermetically sealed joint between the metal frame 41 and the substrate 31.

Indeed, the formation of the joint 33 implies a step in a high temperature oven, which may degrade the elements to be encapsulated.

FIG. 5 illustrates a last step of the method according to the invention wherein a metal lid 61 is hermetically sealed to the metal frame 41. This metal lid 61 is preferably made in titanium and consists in a plate, here with a square shape. Generally, it has a shape and dimensions adapted for covering the frame 41. Thus, the lid 61 is put into contact with the metal frame 41 and a weld 62 is made between the lid 61 and the frame 41, on the outer periphery of this stack.

A method known to one skilled in the art for hermetically sealing two metal parts is welding with a localized laser beam.

The arrows illustrated in FIG. 5 indicate the direction and the localization of the laser beam which allows the weld to be made without providing any extra metal.

In the particular embodiment illustrated in FIG. 5, the weld 62 will be spatially shifted relatively to the brazing 51 while being at least partly included in the perimeter of the substrate 31.

This will notably give the possibility of not deteriorating with the laser beam the brazings 51 for which the thickness is small (1 μm-100 μm) as this might be the case if the brazing 51 and the laser welding site were found on a same vertical axis.

The obtained hermetically sealed casing and illustrated in FIG. 5 has a thickness smaller than that of conventional casings since the brazing joint is partly located in the recess 32 made in the substrate. The impact of the thickness of the brazing joint on the thickness of the casing is therefore reduced.

Generally, the thickness of the obtained casings is comprised between 0.1 mm and 3 mm.

FIG. 6 illustrates an alternative of the steps of the method illustrated in FIGS. 3 and 4 giving the possibility of further reducing the impact of the thickness of the brazing joint.

In this alternative, the brazing joint 33 is totally integrated into the substrate 31.

Thus, the joint 33 only partly fills the groove 32 made in the substrate.

However, in order to be able to braze the substrate 31 to the metal frame 71, the latter should have a particular (convex) structure as illustrated in FIG. 6 in order to be in contact with the brazing joint 33.

Thus, the frame 71 has, like the frame 41, a planar and square portion 71a and, protruding on the portion 71a, a shoulder 71b intended to penetrate into the groove 32 so as to come into contact with the joint 33. This protruding portion 71b ends on the internal wall 711 of the frame 71.

This protruding portion 71b forms a closed curve, similar to that of the recess 32. Its width is however slightly smaller than that of the recess in order to be able to penetrate into the recess. Further, its thickness is sufficient so as to come into contact with the joint 33.

This structure has two advantages.

The first advantage is to totally suppress the impact of the thickness of the brazing joint 33 on the total thickness of the casing which will be obtained after assembling the lid 61.

The second advantage is to locally have over-thickness of metal which may prove to be useful in the case of diffusion of one or several elements making up the brazing joint 33 within the metal frame 71.

Indeed, if one takes the particular case of a brazing joint 33 based on Ni or TiNi50 and of a metal frame 71 based on titanium, it is known that Ni may diffuse over several tens of microns within titanium. Thus, if the thickness of the metal frame is insufficient and if the nickel diffuses as far as the end opposite to the one where brazing takes place, there are risks of brazing the substrate holder (not shown in the diagram of FIG. 6) inter alia used for applying a certain force on the sample during the brazing.

Thus, this embodiment gives the possibility of getting rid of this problem and this, without increasing the impact of the thickness of the metal frame 71 on the final thickness of the casing.

FIG. 7 illustrates another alternative of the step of the method illustrated in FIG. 4, having the purpose of solving the problems related to the alignment between the lid and the metal frame.

The brazing joint 33 is made in accordance with FIG. 3. It is therefore partly integrated into the substrate 31 and not totally integrated.

The metal frame 81 has, like the frame 41, a planar and square portion 81a and, protruding on the portion 81a, a shoulder 81c.

This protruding portion 81c is located on the face of the frame 81 which is not intended to come into contact with the joint 33 and positioned so as to be substantially facing the engraving 32, when the frame 81 is positioned on the joint 33. It ends here on the internal wall 811 of the frame 81.

This protruding portion 81c preferably forms a closed curve similar to that of the recess 32. Its width is preferably at least equal to that of the recess 32.

There again, this particular shape of the frame gives the possibility of locally obtaining an over-thickness of metal which gives the possibility of solving the alignment problems between the lid and the metal frame.

FIG. 8 illustrates an alternative of the step of the method illustrated in FIG. 5 which is adapted to the alternative illustrated in FIG. 7.

Indeed, the FIG. 8 shows a lid 111 in which is made a groove 112. It has the form of a negative of the shoulder 81c of the frame 81.

Thus, the lid 111 will be deposited on the frame 81 by inserting the shoulder 81c into the groove 112.

This configuration therefore gives the possibility of approving the alignment between the lid 111 and the frame 81.

Finally, this configuration gives the possibility of avoiding that the particular shape of the frame 81 has an impact on the total thickness of the casing.

Of course, the alternative illustrated in FIG. 8 may also be modified in order to provide a brazing joint 33 completely integrated into the support 31.

The frame then has to be modified as explained facing FIG. 6 in order to be able to be brazed on the substrate.

FIG. 9 thus illustrates a metal frame 121 which has a T structure, with a planar portion 121a, a protruding portion 121b intended to penetrate into the recess 32 in order to come into contact with the brazing joint and a symmetrical protruding portion 121c of the portion 121b with respect to the planar portion 121a.

This gives the possibility of combining the advantages of the configuration shown in FIG. 6 with those of the configuration shown in FIG. 8.

As mentioned earlier, the brazing joint 33 may be made by methods for deposition in thin layers. For example mention may be made of the use of cathode sputtering for producing this deposit.

FIG. 10 illustrates a brazing joint 91 produced as a thin layer, with a thickness typically comprised between 0.1 μm and 5 μm.

A means for managing the production of such a brazing joint 91, is to produce a deposit by cathode sputtering of the desired material (nickel for example) through a mechanical mask, in order to deposit only material at the groove 32 level.

Such a joint has a dual advantage.

Indeed, not only it has a reduced thickness but furthermore it covers the whole of the walls of the groove 32. This leads to an improvement in the mechanical strength of the brazing, once the brazing annealing has been carried out. Indeed, this gives the possibility of generating a three-dimensional attachment between the substrate 31 and the metal frame 41.

Thus, although the joint is ultra-thin, it is possible to obtain sufficient mechanical strength by means of this type of configuration.

FIG. 11 illustrates another alternative wherein a groove 102 is made in the metal frame 101 and not in the substrate 31. This allows partial integration of the brazing joint 33 into the metal frame 101.

The substrate 31 is then put into contact with the frame 101 and the whole is placed in a brazing oven.

The lid 61 may then be hermetically sealed to the frame 101 as this was described with reference to FIG. 5.

Again, the benefit of this kind of structure in reducing the impact of the thickness of the brazing joint 33 on the total thickness of the casing is well understood.

The alternatives described in connection with FIGS. 6 to 9 may also be adapted to this configuration.

FIG. 12 illustrates another alternative of the step of the method notably illustrated in FIG. 5 and which consists of modifying the lid.

Indeed, another means for producing a casing with reduced thickness consists of using, in the place of the metal lid 61 (as shown in FIG. 5), a lid consisting of a metal frame 141 brazed to an insulating substrate 142 via a brazing joint 143 as shown in FIG. 12.

It should be noted that the structure of FIG. 14 may be adapted to the different configurations described earlier. Thus, both the metal frame 141 but also the metal frame 141 may be shaped (textured).

This alternative embodiment gives the possibility of reducing the amount of metal used. This allows improvement in the compatibility of such a casing with the use of an MRI, by reducing its heating up.

FIG. 13 illustrates another alternative in which, during the first step of the method according to the invention, in addition to the groove 32, a cavity 151 is made in the insulating substrate 31. This cavity is therefore facing the lid 61.

This gives the possibility of receiving different components which have to be encapsulated in a hermetic way like electronic components for example.

This alternative embodiment may also be applied to the lid, a cavity being then made in the latter.

The reference signs inserted after the technical characteristics appearing in the claims have the sole purpose of facilitating the understanding of the latter and would not limit the scope thereof.

1. A method for making a hermetically sealed casing comprising the following steps:
(a) providing a first element wherein a recess is made,
(b) forming a brazing joint in said recess, said joint being at least partly integrated into said recess,
(c) putting a second element facing said first element and said joint,
(d) forming a first hermetically sealed joint between the first and second elements in order to assemble them and form an assembly,
(e) superposing a lid to said assembly, and
(f) forming a second hermetically sealed joint between said assembly and said lid.

2. The method according to claim 1, wherein the brazing joint is partly integrated into said recess, the second element then being planar.

3. The method according to claim 1, wherein the brazing joint is totally integrated into said recess, the second element including a first protruding portion intended for penetrating into the recess during step (c) for coming into contact with said brazing joint.

4. The method according to claim 1, wherein the first element is a sheet-shaped substrate while the second element is a metal frame.

5. The method according to claim 1, wherein the first element is a metal frame while the second element is a sheet-shaped substrate.

6. The method according to claim 4, wherein the metal frame includes a second protrusion portion, on its face opposite to the one intended to come into contact with the brazing joint.

7. The method according to claim 6, wherein the lid has a groove into which is inserted the second protruding portion, during step (e).

8. The method according to claim 4, in which, during step (a), a cavity is also made in the substrate.

9. The method according to claim 1, wherein during step (b), the brazing joint is made as a thin layer, covering the walls of the recess.

10. A method for encapsulating a device consisting of applying the method according to claim 1 and of mounting at least one component of said device to be encapsulated on said first element, after step (b).

11. A hermetically sealed casing comprising:
a first element including a recess,
a second element hermetically connected to the first element through a first joint, at least partly integrated into said recess, and
a lid hermetically connected to the first or second element through a second joint.

12. The hermetically sealed casing according to claim 11, wherein the second element is planar.

13. The hermetically sealed casing according to claim 11, wherein the second element includes a first protruding portion introduced into said recess.

14. The hermetically sealed casing according to claim 11, wherein the first element is a substrate as a sheet while the second element is a metal frame.

15. The hermetically sealed casing according to claim 11, wherein the first element is a metal frame while the second element is a sheet-shaped substrate.

16. The hermetically sealed casing according to claim 14, wherein the metal frame includes a second protruding portion in contact with the lid.

17. The hermetically sealed casing according to claim 16, wherein the lid has a groove into which is inserted the second protruding portion.

18. The hermetically sealed casing according to claim 14, wherein the substrate includes a cavity facing the lid.
